(19) United States
(12) Patent Application Publication
(10) Pub. No.: US 2025/0103770 A1
(43) Pub. Date: Mar. 27, 2025

(54) END-TO-END DESIGN METHOD FOR DESIGNING A FREE-FORM SURFACE SYSTEM

(71) Applicants: Tsinghua University, Beijing (CN); HON HAI PRECISION INDUSTRY CO., LTD., New Taipei (TW)

(72) Inventors: JUN ZHU, Beijing (CN); WEI-CHEN WU, Beijing (CN); MENG-HUI WANG, Beijing (CN)

(21) Appl. No.: 18/889,572

(22) Filed: Sep. 19, 2024

(30) Foreign Application Priority Data
Sep. 27, 2023 (CN) 202311267086.X

(51) Int. Cl. G06F 30/20; G06F 30/10

(52) U.S. Cl. CPC G06F 30/20; G06F 30/10

(57) ABSTRACT

An end-to-end design method for designing a free-form surface system comprises: S1, providing an initial plane system, solving a first-order geometric structure according to the initial plane system, the first-order geometric structure comprising multiple curved surfaces, and determining an optical focal length of each curved surface according to a field curvature equation and the focal length equation; S2, determining the optical focal length of each curved surface and adjusting the position of the curved surface using a flat field condition and a linear astigmatism elimination equation; S3, determining a fast design strategy for the first-order geometric structure, a design strategy meets at least one of the following three conditions: a focal length of the system is equal to a given value; and S4, constructing the free-form surface system using a surface normal correction method.

### CROSS-REFERENCE TO RELATED APPLICATIONS

This application claims all benefits accruing under 35 U.S.C. § 119 from China Patent Application No. 202311267086.X, filed on Sep. 27, 2023, in the China National Intellectual Property Administration, the contents of which are hereby incorporated by reference.

### FIELD

The present disclosure relates to the field of optical design, and in particular to an end-to-end design method for designing a free-form surface system.

### BACKGROUND

In the traditional optical design model, designers need to participate in solving the initial structure of the system and try various optimization strategies to improve the image quality step by step. The current design method for free-form surface systems still takes several minutes or even hours to calculate an design. Although an optical system with high image quality can be obtained, if the result does not meet the design requirements in terms of volume, processing, and assembly, it is necessary to recalculate and wait for several minutes to hours again. Long waits can easily interrupt the designer's design ideas and work rhythm. If the speed of the design process can be increased several times, an optical system with high imaging quality can be directly obtained within the time of a single optimization of traditional optical design.

### BRIEF DESCRIPTION OF THE DRAWINGS

Implementations of the present technology will now be described, by way of example only, with reference to the attached figures, wherein:

FIG. 1 is a schematic diagram of a structure of an initial three-mirror system provided by an embodiment of the present disclosure.

FIG. 2 is a schematic diagram of an astigmatism correction transformation vector provided by an embodiment of the present disclosure.

### DETAILED DESCRIPTION

The disclosure is illustrated by way of example and not by way of limitation in the figures of the accompanying drawings in which like references indicate similar elements. It should be noted that references to “another,” “an,” or “one” embodiment in this disclosure are not necessarily to the same embodiment, and such references mean “at least one.”

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale, and the proportions of certain parts have been exaggerated to illustrate details and features of the present disclosure better.

Several definitions that apply throughout this disclosure will now be presented.

The term “substantially” is defined to be essentially conforming to the particular dimension, shape, or other feature which is described, such that the component need not be exactly or strictly conforming to such a feature. The term “comprise,” when utilized, means “comprise, but not necessarily limited to”; it specifically indicates open-ended inclusion or membership in the so-described combination, group, series, and the like. The term of “first”, “second” and the like, are only used for description purposes, and should not be understood as indicating or implying their relative importance or implying the number of indicated technical features. Thus, the features defined as “first”, “second” and the like expressly or implicitly comprise at least one of the features. The term of “multiple times” means at least two times, such as two times, three times, etc., unless otherwise expressly and specifically defined.

An embodiment of the present disclosure provides an end-to-end design method for designing a free-form surface system, which comprises the following steps:
S1, providing an initial plane system, solving a first-order geometric structure according to the initial plane system, the first-order geometric structure comprising multiple curved surfaces, and determining an optical focal length of each curved surface according to a field curvature equation and the focal length equation;
S2, determining the optical focal length of each curved surface and adjusting the position of the curved surface using a flat field condition and a linear astigmatism elimination equation;
S3, determining a fast design strategy for the first-order geometric structure, a design strategy meets at least one of the following three conditions: a focal length of the system is equal to a given value, a sum of the optical focal lengths of each curved surface ψ is 0, and a parameter γ related to astigmatism is 0; and
S4, constructing the free-form surface system using a surface normal correction method, further improving an image quality using an iterative process of image plane correction and surface correction, and obtaining the final design result.

Below, each step of the end-to-end design method for designing a free-form surface system provided by the present disclosure will be described in detail.

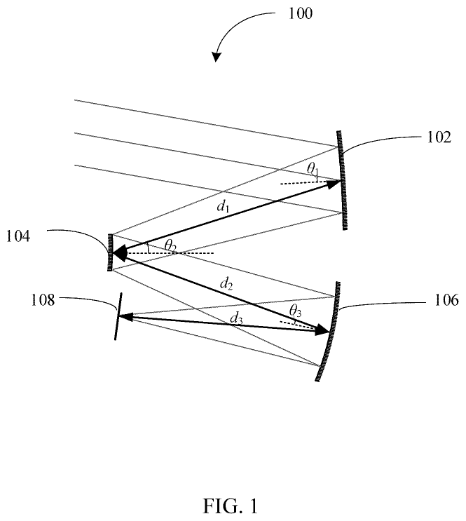

In step S1, a position of the curved surface is described by a distance d and an incident angle θ of the curved surface. If a main ray of a central field of view is set as a central ray, the distance d of the curved surface is the distance between the corresponding points of the central ray at the adjacent curved surface, and the incident angle θ is the incident angle of the central ray on each curved surface. Please refer to FIG. 1, in this embodiment, the initial plane system is a three-mirror system, which comprises a primary mirror 102, a secondary mirror 104, a third mirror 106 and an image plane 108. Among them, d₁ is a distance between the primary mirror 102 and the secondary mirror 104, d₂ is a distance between the secondary mirror 104 and the third mirror 106, and d₃ is a distance between the third mirror 106 and the image plane 108. θ₁ is an incident angle of a central light on the primary mirror, θ₂ is an incident angle of the central light on the secondary mirror, and θ₃ is an incident angle of the central light on the third mirror 106.

Before determining the first-order geometric structure, the focal length of each curved surface is determined by the field curvature and astigmatism correction equations. In an off-axis case, a curvature radius is not accurate enough to describe the focal length, so an object-image distance of the central field of view on each curved surface is used to express a focal length φ of the curved surface, wherein,

$$ϕ = \frac{{n}^{′}}{{l}_{i}} - \frac{n}{{l}_{o}} .$$

n′ and n are refractive indices before and after a certain curved surface, respectively, and li and lo are the image distance and object distance of the curved surface, respectively. When calculating the first-order geometric structure, the optical transmission matrix is used to analyze the system. The transmission matrix of the kth curved surface is Tₖ, and the transmission matrix of the kth curved surface spacing is Dₖ, then

$${T}_{k} = [ \begin{matrix}1 & 0 \\ {ϕ}_{k} & 1\end{matrix} ] , {D}_{k} = [ \begin{matrix}1 & - \frac{{d}_{k}}{{n}_{k}} \\ 0 & 1\end{matrix} ] .$$

Wherein φₖ is the focal length of the kth curved surface, dk and nₖ are the distance and refractive index between the kth curved surface and the (k+1)th curved surface, respectively. If the imaging system has N curved surfaces, the optical transmission matrix of the system is

$$[ \begin{matrix}{T}_{A} & {T}_{B} \\ {T}_{C} & {T}_{D}\end{matrix} ] = {T}_{N} {D}_{N - 1} {T}_{N - 1} … {D}_{2} {T}_{1} {D}_{1} .$$

In order to meet the given effective focal length (EFL), the spacing d and the optical power φ of each curved surface need to meet

$$EFL = - \frac{1}{{T}_{C}} .$$

The next step is to convert a curved surface optical power into specific curved surface parameters to obtain the first-order geometric structure. When using a spherical curved surface, a rotationally symmetric surface, to establish the first-order geometric structure of the off-axis system, a same radius of curvature will correspond to different optical powers on the meridian and sagittal planes. For high-performance systems with a large field of view and aperture, in order to eliminate obstruction, the curved surface often has a larger off-axis angle, and the optical power difference corresponding to the same radius of curvature on the meridian and sagittal planes will also be greater. Therefore, the embodiment of this method will use the bracelet surface to apply to the first-order geometric structure. In the off-axis system, the bracelet surface can have different radii of curvature on the meridian and sagittal planes. The use of the bracelet surface can ensure that the optical power of each curved surface determined is consistent on the meridian and sagittal planes. From the Coddington formula, we can know that the radius of the bracelet surface on the meridian and sagittal planes can be determined by using the object-image distance of each curved surface, as shown in the following equation:

$$\frac{{n}^{′} {cos}^{2} ( {θ}^{′} )}{{l}_{i}} - \frac{n {cos}^{2} ( θ )}{{l}_{o}} = \frac{{n}^{′} cos ( {θ}^{′} ) - n cos ( θ )}{{R}_{T}} \\ \frac{{n}^{′}}{{l}_{i}} - \frac{n}{{l}_{o}} = \frac{{n}^{′} cos ( {θ}^{′} ) - n cos ( θ )}{{R}_{S}}$$

Wherein, θ′ and θ are the incident angle and the exit angle, respectively, and RT and RS are the curvature radii on the meridian and sagittal planes, respectively.

In this step S2, the field curvature is an important aberration. In the absence of astigmatism, if you want to obtain a flat image surface, you need to make the Petzval curvature 0, that is, you need to make the sum of the focal lengths of each curved surface ψ is 0, as shown in the formula

$$ψ = {\sum }_{k = 1}^{N} {ϕ}_{k} .$$

The above is the flat field condition. Substituting the formula

$$ϕ = \frac{{n}^{′}}{{l}_{i}} - \frac{n}{{l}_{o}}$$

into the formula

$$ψ = {\sum }_{k = 1}^{N} {ϕ}_{k} ,$$

you can get the equation with the object-image distance of each curved surface as a variable.

In off-axis systems, linear astigmatism with respect to field asymmetry is often the main component of aberrations. When calculating the first-order geometric structure, we choose to use the equation given by Chang to eliminate this linear astigmatism with respect to field asymmetry, as shown in the following equation:

$$γ = {\sum }_{p = 1}^{N - 1} [ ( 1 + {m}_{p} ) tan {θ}_{p} {\prod }_{q = p + 1}^{N} {m}_{q} ] + ( 1 + {m}_{N} ) tan {θ}_{N}$$

Wherein, mₖ is the ratio of the image distance of each curved surface to the object distance, θₖ is the incident angle of the central light on each curved surface, and when γ is 0, the linear astigmatism with respect to field asymmetry is eliminated. Wherein, if the object plane is not tilted, then the image plane is perpendicular to the central light.

The above equation has the characteristic that it can be regarded as the scalar product of two vectors. Here, N=3 is taken as an example, as shown in the following equation:

$$γ = A \cdot B = ( ( 1 + {m}_{1} ) {m}_{2} {m}_{3} , ( 1 + {m}_{2} ) {m}_{3} , 1 + {m}_{3} ) \cdot ( tan {θ}_{1} , tan {θ}_{2} , tan {θ}_{3} )$$

Wherein, vector A is only related to the object-image distance of each curved surface, that is, it is closely related to the optical power of each curved surface; and vector B is only related to the incident angle. When vector A is orthogonal to vector B, linear astigmatism with respect to field asymmetry is eliminated.

The astigmatism correction transformation based on formula

$$γ = {\sum }_{p = 1}^{N - 1} [ ( 1 + {m}_{p} ) tan {θ}_{p} {\prod }_{q = p + 1}^{N} {m}_{q} ] + ( 1 + {m}_{N} ) tan {θ}_{N}$$

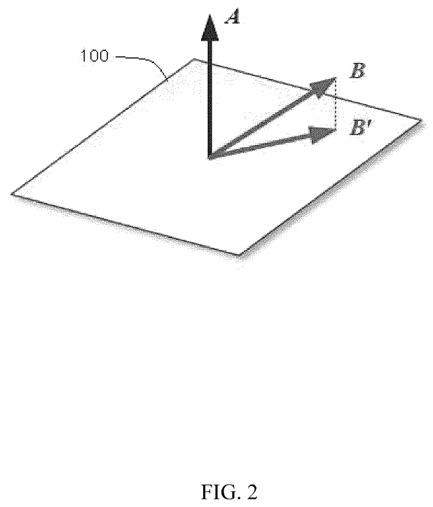

will be described below, which will be used to correct the position of the curved surface in this method. The vector diagram of the astigmatism correction transformation is shown in FIG. 2. When the optical power of each curved surface is determined, the A vector is also determined. At this time, the B vector can only make γ equal to 0 when it is located on the plane 100 perpendicular to the A vector. The angles of each curved surface in the given initial plane system usually cannot make the vector B located on the plane 100. Therefore, the vector B can be projected onto the plane 100 by projection transformation to obtain the vector B′, as shown in FIG. 2. After the projection transformation of FIG. 2, the vector B becomes the vector B′ that is orthogonal to the vector A. When the vector A remains unchanged, the scalar product γ of the vector B′ and A becomes 0, and the vector B′ can minimize |B−B′|. To understand this projection transformation from the perspective of system structure, when the optical power is determined, this transformation makes each curved surface eliminate the asymmetric linear astigmatism of the field of view under the minimum incident angle adjustment. This projection transformation can also be called astigmatism correction transformation.

In step S3, the input of this method is the system parameters such as focal length, field angle, and F number, as well as a plane system according to the designer's initial conception. In order to prevent the final system from deviating too much from the initial plane system set by the designer, the spacing d of the curved surfaces in this method remains unchanged when determining the first-order geometry, and the incident angle θ of the central light on each curved surface will only change when using the astigmatism correction transformation. Assuming that there are a total of N curved surfaces, the surface spacing d₁, d₂, . . . , d_{N} is determined according to the given plane system. Then the difference between the image distance of the kth curved surface and the object distance of the (k+1)th curved surface is known as dk. If the image distances of the first (N−1) curved surfaces are known, the object distances of the 2nd to Nth curved surfaces can be obtained. At the same time, the object distance of the first curved surface is a given object distance, usually infinite, and the image distance of the Nth curved surface is d_{N}, so the object-image distance of each curved surface can be obtained. According to the formula

$$ϕ = \frac{{n}^{′}}{{l}_{i}} - \frac{n}{{l}_{o}} ,$$

the object-image distance of each curved surface can be used to solve the focal length of each curved surface. In summary, if the image distance of the first (N−1) curved surfaces is known, the focal length of each curved surface can be obtained. Therefore, the image distance of the first (N−1) curved surfaces will be set as a variable to solve the relevant equations.

The first-order geometric structure design strategy of this method is that the system satisfies the following three conditions as much as possible: the focal length of the system is equal to the given value, as shown in the formula

$$EFL = - \frac{1}{{T}_{C}} ,$$

which is called the focal length equation in this invention; the sum of the focal lengths of each curved surface ψ is 0, as shown in the formula

$$ψ = {\sum }_{k = 1}^{N} {ϕ}_{k} ,$$

which is called the field curvature equation in this invention; the parameter γ related to astigmatism is 0, as shown in the formula

$$γ = {\sum }_{p = 1}^{N - 1} [ ( 1 + {m}_{p} ) tan {θ}_{p} {\prod }_{q = p + 1}^{N} {m}_{q} ] + ( 1 + {m}_{N} ) tan {θ}_{N} ,$$

which is called the astigmatism equation in this invention. The present disclosure will use the above three equations to solve the focal length and correct the incident angle of each curved surface. In the case of multiple solutions in the process of solving the equation, the present disclosure will calculate the corresponding first-order geometric structure respectively, and automatically select the system with the best image quality for the subsequent construction of the free-form surface system.

The end-to-end design method for designing the free-form surface system provided by the present disclosure selects different design strategies according to the number of reflectors, and is currently applicable to a four-reflector system at most. According to the above description, there are (N−1) variables in a system containing N reflectors. When N is greater than 3, the number of variables will not be less than the number of equations, and the design strategy is to solve the focal power of the first-order geometric structure by combining three equations. When N is not greater than 3, the number of variables will be less than the number of equations, and the design strategy is to combine three conditions and astigmatism correction transformation to determine the first-order geometric structure.

The following will introduce the first-order geometric structure design strategies of two reflectors (N=2), three reflectors (N=3) and four reflectors (N=4).

First-order geometric structure design strategy of three-reflector system is discussed below.

According to the description of the variables in the system in the previous article, there are two variables in the three-reflector system, which are the image distances of the first two reflectors. At this time, the number of variables will be less than the number of equations, and the first-order geometric structure design strategy of the three-mirror system is divided into two steps.

The first step is to first solve the optical power by combining the field curvature equation and the focal length equation, and then use the astigmatism correction transformation to correct the surface position while ensuring the solved optical power, so that the system can finally meet the three conditions at the same time. Solving the optical power by combining the field curvature equation and the focal length equation (there is an analytical solution at this time) can make the system meet the first two conditions. At this time, the surface position and optical power do not satisfy the astigmatism equation, that is, γ is not 0. Then, the astigmatism correction transformation is used to adjust the incident angle at the current optical power to satisfy the astigmatism equation. In this way, the parameters of the first-order geometric structure that can meet the three conditions at the same time are determined.

Before the astigmatism correction transformation, if the absolute value of γ is relatively small, it means that the surface position at this time is close to the position that satisfies the astigmatism equation. Therefore, the incident angle adjustment caused by the astigmatism correction transformation will also be relatively small, and the system will not be blocked due to the adjustment of the incident angle, and there is no need to enter the second step at this time. This situation corresponds to some geometric structures with relatively small astigmatism, such as the three-mirror anastigmat (TMA) structure. When the absolute value of γ is relatively large, the change in astigmatism correction will cause the surface position to move more, and the use of astigmatism correction transformation may cause the system to be blocked. This actually means that it may be difficult to find a solution that satisfies all three conditions around the initial plane system. Therefore, a fast and search process for optical power distribution is required as the second step of the three-mirror system design strategy.

The second step will first establish multiple first-order geometric structures with different optical power distributions, and then perform astigmatism correction transformations on these first-order geometric structures to obtain multiple systems with γ of 0. Finally, the system with the best imaging quality in the unobstructed range is selected as the final first-order geometric structure. Different optical power distributions are obtained by combining the focal length equation and the astigmatism equation with different γ, and analytical solutions exist at this time. Among them, γ is selected from 0 to the positive and negative directions in a certain step size. The astigmatism correction transformation is actually to find the next geometric structure with small aberration potential under the current optical power with the minimum adjustment of the incident angle. Solving the astigmatism equation with different γ values does not only consider the astigmatism aberration, but its essence is to obtain a variety of different focal power distributions. After that, a series of first-order geometric structures with small aberration potential can be obtained through astigmatism correction transformation. Searching for γ from 0 means that the surface position adjustment caused by astigmatism correction ranges from small to large. When the curved surface is blocked, the search process will stop. This method uses the average value of the RMS spot radius of each field of view to evaluate the imaging quality of a series of geometric structures, and the best results will be combined with the direct design method to construct a free-form surface system.

Designing strategy for the first-order geometric structure of the two-mirror system: for the two-mirror system, if the rules for selecting variables are followed as described above, there is only one variable, the primary mirror image distance, which will not be conducive to solving the equation. When this method deals with the case of the two-mirror system, the distance between the secondary mirror and the image plane is also set as a variable, so that a strategy similar to that in the three-mirror system can be implemented in the two-mirror system.

Design strategy for the first-order geometric structure of the four-mirror system: in the four-mirror system, after determining the curved surface spacing and the incident angle according to the given initial plane system, there are three variables in the four-mirror system, which are the image distances of the first three mirrors. At this time, the number of variables is equal to the number of three equations. The focal length equation, field curvature equation and astigmatism equation can be directly combined to obtain the optical focal length of each curved surface and determine the first-order geometric structure. The optimization algorithm can be used to calculate the numerical solution to this nonlinear equation group. This method uses the general global optimization algorithm in the 1stopt software to solve this problem. This method can obtain the calculation results without relying on the selection of initial values. It is fast, stable and universal, and can obtain correct results in most cases.

In step S4, first is the construction of the free-form surface system. Since the first-order geometric structure has been used for the distribution of focal length and angle correction based on astigmatism and field curvature, and many low-level aberrations have been corrected, the direct design method can be used to correct high-order aberrations, and excellent imaging quality can be quickly obtained. The direct design method used in this method is the surface normal correction method, which can quickly realize the construction of a free-form surface imaging system.

In this direct design method, each curved surface needs to go through multiple fitting processes. By simultaneously considering the fitting method of coordinates and normals, the original surface shape data points of a curved surface and the corrected normal are fitted to obtain a free-form surface. The original curved surface shape data points are obtained by ray tracing of characteristic rays of different apertures in multiple fields of view. The corrected normal is determined by the incident light and the outgoing light according to the law of reflection, where the incident light maintains its original direction and the outgoing light points to the ideal image point. The free-form surface system is established by fitting each curved surface in the system in turn. The process of fitting all free-form surfaces in the system needs to be performed multiple times until the imaging quality is no longer improved, and the construction of the free-form surface imaging system is completed.

Then the free-form surface system is corrected. The determination of the image plane angle in the first-order geometric structure only considers the linear astigmatism of the asymmetric field of view. In order to further improve the imaging quality, it is necessary to use the iterative process of image plane correction and surface normal correction. In this iterative process, the image plane correction considers the aberration terms related to the image plane, and the surface correction also uses the direct design method of surface normal correction. Since the imaging quality of the system is already excellent before the image plane correction, it can often be completed within a few iterations. When the imaging quality of the system meets the actual required standards, the final free-form surface system is obtained.

The entire design process of the end-to-end design method for designing the free-form surface system provided by the present disclosure is as follows: After the designer gives the system parameters and the initial plane system, the method first determines the surface position and optical focal length of each curved surface in the first-order geometric structure according to the flat field condition and the linear astigmatism elimination equation, and then uses the surface normal correction method to construct the free-form surface imaging system. Finally, the iterative process of image plane correction and surface correction is used to further correct the free-form surface imaging system to obtain the final design result.

Furthermore, according to the free-form surface system finally obtained, a mirror surface that meets the parameters is made, and after installation, an optical lens element can be obtained.

The design method proposed in this paper realizes the end-to-end rapid design of the free-form surface imaging system, which may promote the change of the optical design mode. The method is instant and efficient. Designers can often obtain excellent design results after several rapid trials of the end-to-end design process. For designers who are familiar with various structures of free-form surface systems, it is likely that one or two attempts can be made to obtain an off-axis imaging system with excellent imaging quality. For beginners of optical design or practitioners in other fields of optics, the desired design results can usually be obtained after several trials.

The input of the end-to-end design method proposed in the present disclosure is an initial plane system. The position of the curved surface does not move or only moves in a small range during the automatic design process. This feature ensures that the optical path structure of the system can be in accordance with the designer's general idea. As long as the designer reasonably places the plane position, the possibility of beam obstruction or lens interference is reduced. Even if these phenomena occur in the design result, the designer only needs to simply adjust the plane position during the trial process to avoid them.

If you need to design a compact optical system, you can give a loose initial plane system during the initial end-to-end design process. Based on the output system obtained in the initial end-to-end design process, the designer can predict the curved surface shape and size of the output system in the subsequent trial and error process. After that, the designer can continuously change the position of the plane to reduce the system volume to achieve a compact optical structure.

Please see the table below, which shows the comparison between the system designed by the end-to-end design method for designing free-form surface system provided by the present disclosure and the prior art.

| | Design example | | |
|---|---|---|---|
| | structure and | | |
| Design | system | Calculation | |
| method | parameters | time | |
| Existing | Three- | Focal length: 57 mm, | 3.14 H |
| technology | mirror | field of view: 8° × 6° | |
| 1 | system | F value: 1.9, | |
| | | working band: long-wave infrared | |
| Existing | Three- | Focal length: 60 mm, | 5 M 56 S |
| technology | mirror | field of view: 3° × 3° | |
| 2 | system | F value: 1.5, | |
| | | working band: long-wave infrared | |
| Existing | Four-mirror | Focal length: 250 mm, | 5 M |
| technology | system | field of view: 2° × 7.2° | |
| 3 | | F value: 2.5, | |
| | | working band: visible | |
| Embod- | Three- | Focal length: 540 mm, | 49 S |
| iment | mirror | field of view: 3° × 3°, | |
| of the | system | F value: 3.0, working band: visible | |
| present | Three- | Focal length : 180 mm, | 1 M 12 S |
| disclosure | mirror | field of view: 6° × 6° | |
| | system | F value: 1.8, | |
| | | working band: long-wave infrared | |
| | Four-mirror | Focal length: 3000 mm, | 1 M 51 S |
| | system | field of view: 1.5° × 1.5° | |
| | | F value: 8.0, working band: visible | |

The above table lists several representative free-form surface system design examples designed by the free-form surface system automatic design method in the prior art. These design examples mainly comprise three-mirror system and four-mirror system. At the same time, the above table also gives the specific implementation examples designed by the free-form surface system end-to-end automatic design method provided by the present disclosure. It can be seen from the above table that the free-form surface system end-to-end automatic design method proposed by the present disclosure is not only suitable for high-performance imaging systems, but also can realize end-to-end rapid automatic design.

It is to be understood that the above-described embodiments are intended to illustrate rather than limit the present disclosure. Variations may be made to the embodiments without departing from the spirit of the present disclosure as claimed. Elements associated with any of the above embodiments are envisioned to be associated with any other embodiments. The above-described embodiments illustrate the scope of the present disclosure but do not restrict the scope of the present disclosure.

Depending on the embodiment, certain of the steps of a method described may be removed, others may be added, and the sequence of steps may be altered. The description and the claims drawn to a method may comprise some indication in reference to certain steps. However, the indication used is only to be viewed for identification purposes and not as a suggestion as to an order for the steps.

What is claimed is:

1. An end-to-end design method for designing a free-form surface system, comprising:
S1, providing an initial plane system, solving a first-order geometric structure according to the initial plane system, wherein the first-order geometric structure comprises multiple curved surfaces, and determining an optical focal length of each of the multiple curved surfaces according to a field curvature equation and the focal length equation;
S2, determining the optical focal length of each of the multiple curved surfaces and adjusting a position of each of the multiple curved surfaces using a flat field condition and a linear astigmatism elimination equation;
S3, determining a design strategy for the first-order geometric structure, wherein the design strategy meets at least one of following three conditions: a focal length of the system being equal to a given value, a sum of the optical focal lengths of each of the multiple curved surfaces, ψ, is zero (0), and a parameter γ related to astigmatism is zero (0); and
S4, constructing the free-form surface system by applying a surface normal correction method, further improving an image quality using an iterative process of image plane correction and surface correction, and obtaining the final design result.

2. The method of claim 1, wherein in step S1, positions of the multiple curved surfaces are described using a spacing d and an incident angle θ of the multiple curved surfaces, a main ray of a central field of view is set as a central ray, the spacing d of the curved surfaces is a distance between the central ray at corresponding points of adjacent curved surfaces, and the incident angle θ is the incident angle of the central ray on each curved surface.

3. The method of claim 1, wherein in step S1, before determining the first-order geometric structure, a focal power of each curved surface is determined by the field curvature and astigmatism correction equations, and in an off-axis case, a focal power φ of the off-axis curved surface is expressed by an object-image distance of the central field of view at each of the multiple curved surfaces, wherein
$$ϕ = \frac{{n}^{′}}{{l}_{i}} - \frac{n}{{l}_{o}} ,$$
n′ and n are refractive indices before and after a certain curved surface, and lᵢ and lₒ are an image distance and an object distance of the off-axis curved surface, respectively.

4. The method of claim 1, wherein in step S1, when calculating the first-order geometric structure, an optical transmission matrix is applied to analyze the free-form surface system, a transmission matrix of a kth curved surface of the multiple curved surface is Tₖ, and the transmission matrix of the kth curved surface spacing is Dₖ, wherein:
$${T}_{k} = [ \begin{matrix}1 & 0 \\ {ϕ}_{k} & 1\end{matrix} ] , {D}_{k} = [ \begin{matrix}1 & - \frac{{d}_{k}}{{n}_{k}} \\ 0 & 1\end{matrix} ] ,$$
where φₖ is an optical power of the kth curved surface, dₖ and nₖ are a distance and a refractive index between the kth curved surface and a (k+1)th curved surface of the multiple curved surfaces, respectively.

5. The method of claim 1, wherein in step S2, in an absence of astigmatism, a sum of the optical powers of each of the multiple curved surfaces ψ is zero (0).

6. The method of claim 1, wherein in step S3, a spacing d of each of the multiple curved surfaces is kept constant when determining the first-order geometric structure, and an incident angle θ of a central light on each curved surface is variable only when an astigmatism correction transformation is applied.

7. The method of claim 1, wherein the multiple curved surfaces comprises N curved surfaces, and surface spacings d₁, d₂, . . . , d_{N} are determined according to a given plane system, and then a difference between an image distance of a kth curved surface of the N curved surface and an object distance of a (k+1)th curved surface of the N curved surface is dₖ, and image distances of first (N−1) curved surfaces of the N curved surfaces are known, and object distances of a second to a Nth curved surfaces of the N curved surface are obtained, the object distance of a first curved surface of the N curved surface is pre-determined to be infinite, and an image distance of the Nth curved surface is d_{N}, thereby obtaining the object-image distance of each of the N curved surfaces.

8. The method of claim 1, wherein an optical power of each of the multiple curved surfaces is calculated by applying an object-image distance of each of the multiple curved surfaces according to formula of
$$ϕ = \frac{{n}^{′}}{{l}_{i}} - \frac{n}{{l}_{o}} .$$

9. The method of claim 1, wherein, in step S3, determining the first-order geometric structure design step of the three-mirror system further comprises:
combining a field curvature equation and a focal length equation to calculate the optical focal length, and applying an astigmatism correction transformation to correct a surface position while keeping the calculate optical focal length at constant, and repeating calculations of the optical focal length and the surface position until the three conditions are met at the same time; and
establishing multiple first-order geometric structures each with different optical focal length distributions, and then performing astigmatism correction transformation on the multiple first-order geometric structures respectively to obtain multiple systems with γ being zero (0), and selecting a final first-order geometric structure within an unobstructed range.

10. The method of claim 1, wherein in step S4, the surface normal correction method comprises: reiteratively applying a fitting process to each curved surface of the multiple curved surfaces, wherein original surface shape data points of a curved surface and a corrected normal are fitted to obtain a free-form surface by a fitting method that simultaneously considers coordinates and normal; the original surface shape data points are obtained by ray tracing characteristic rays of different apertures in a plurality of fields of view; the corrected normal is determined by an incident ray and an outgoing ray according to a law of reflection, wherein the incident ray keeps its direction unchanged and outgoing ray points to an ideal image point.
